(19) United States
(12) Patent Application Publication
(10) Pub. No.: US 2017/0213926 A1
(43) Pub. Date: Jul. 27, 2017

(54) ASSEMBLY COMPRISING A PHOTOVOLTAIC MODULE APPLIED TO A CIRCULABLE ZONE

(71) Applicants: COMMISSARIAT A L'ENERGIE ATOMIQUE ET AUX ENERGIES ALTERNATIVES, Paris (FR); COLAS, Boulogne Billancourt (FR)

(72) Inventors: Julien GAUME, La Tour Du Pin (FR); Eric COQUELLE, Versailles (FR); Jean-Luc GAUTIER, Guyancourt (FR); Stephane GUILLEREZ, Lepin Le Lac (FR); Lionel SICOT, Chambery (FR)

(73) Assignees: COMMISSARIAT A L'ENERGIE ATOMIQUE ET AUX ENERGIES ALTERNATIVES, Paris (FR); COLAS, Boulogne Billancourt (FR)

(21) Appl. No.: 15/328,337

(22) PCT Filed: Jul. 27, 2015
(86) PCT No.: PCT/EP2015/067109

§ 371 Date: Jan. 23, 2017

(30) Foreign Application Priority Data
Jul. 28, 2014 (FR) 14 57275

(51) Int. Cl. H01L 31/048; H01L 31/18; H02S 20/21; H01L 31/05

(52) U.S. Cl. CPC H01L 31/0481; H01L 31/0504; H01L 31/1864; H01L 31/1876; H02S 20/21

(57) ABSTRACT

A photovoltaic structure including an assembly of plural photovoltaic cells arranged side by side and electrically connected together, and an assembly encapsulating the plural photovoltaic cells. The encapsulating assembly and assembly of plural photovoltaic cells is situated between first and second layers, and a fixation layer situated between a circulable zone and a photovoltaic module, enabling adherence of the photovoltaic module to the circulable zone. The first layer includes at least one transparent polymer material and plural panels independent of each other, each panel situated facing at least one photovoltaic cell, to form a discontinuous front face of the photovoltaic module, and rigidity of the encapsulating assembly is defined by a Young's modulus of the encapsulation material greater than or equal to 75 MPa at ambient temperature and a thickness of the encapsulating assembly is between 0.4 and 1 mm.

### TECHNICAL FIELD

The present invention relates to the field of photovoltaic modules, comprising an assembly of photovoltaic cells electrically connected together, and notably so-called “crystalline” photovoltaic cells, that is to say which are based on silicon crystals or silicon polycrystals.

The invention may be implemented in numerous applications, it being particularly concerned by applications that require the use of photovoltaic modules that are light, flexible and robust vis-à-vis impacts and high mechanical loads. It thus finds privileged application for its integration in circulable zones, for pedestrians and/or vehicles, such as roads or roadways, bicycle paths, industrial platforms, squares, pavements, among others. Such an application is currently designated by the expression “solar roadway”.

The invention thus proposes a photovoltaic structure assembly comprising a photovoltaic module applied to a circulable zone, the use of such a photovoltaic module for the application thereof on a circulable zone, as well as a method for producing such a photovoltaic structure assembly.

### STATE OF THE PRIOR ART

A photovoltaic module is an assembly of photovoltaic cells arranged side by side between a first transparent layer forming a front face of the photovoltaic module and a second layer forming a rear face of the photovoltaic module.

The first layer forming the front face of the photovoltaic module is advantageously transparent to enable the photovoltaic cells to receive a luminous flux. It is traditionally produced from a single glass panel, having a thickness of the order of 3 mm. The second layer forming the rear face of the photovoltaic module may for its part be made of glass, metal or plastic, among others. It is normally formed by a polymeric structure based on an electrically insulating polymer, for example of polyethylene terephthalate (PET) or polyamide (PA) type, which can be protected by one or more layers based on fluorinated polymers, such as polyvinyl fluoride (PVF) or polyvinylidene fluoride (PVDF), and having a thickness of the order of 300 μm.

The photovoltaic cells may be electrically connected together in series by electrical contact elements, known as connecting conductors, and formed for example by copper strips, respectively arranged against the front faces (faces located facing the front face of the photovoltaic module intended to receive a luminous flux) and rear faces (faces located facing the rear face of the photovoltaic module) of each of the photovoltaic cells.

Furthermore, the photovoltaic cells, situated between the first and second layers forming respectively the front and rear faces of the photovoltaic module, are encapsulated. Conventionally, the encapsulant selected corresponds to a polymer of elastomer (or rubber) type, and may for example consist in the use of two layers (or films) of poly(ethylene vinyl acetate) (EVA) between which are arranged the photovoltaic cells and the connecting conductors of the cells. Each layer of EVA may have a thickness of at least 0.3 mm and a Young's modulus less than or equal to 30 MPa at ambient temperature.

Normally again, the method for producing the photovoltaic module comprises a single step of rolling of the different layers described previously, at a temperature greater than or equal to 140° C., or even 150° C., and for a period of at least 8 minutes, or even 15 minutes. After this rolling operation, the two layers of EVA have melted to form only a single layer in which the photovoltaic cells are immersed.

Nevertheless, these embodiments of a photovoltaic module known from the prior art are not entirely satisfactory and have several drawbacks for at least some of the applications thereof.

Within the scope of applications of the solar roadway type, a need has arisen to use roads or roadways as energy production means during the day, whether for supplying buildings situated nearby (companies, eco-districts, solar farms, individual houses, among others) or to supply the electricity grid or traffic circulation aid devices, for example.

Thus, firstly, the presence of a glass panel to form the front face of the photovoltaic module is not compatible with certain applications of the photovoltaic module which may require a relative lightness and a facility of shaping the module. On the contrary, the designs of the prior art using glass on the front face of the photovoltaic modules imply obtaining a high weight of the module and a limited integration capacity.

For an application of solar roadway type, photovoltaic modules with a front face made of glass are not, one the one hand, sufficiently flexible to meet the deformation of a road, this being of the order of 1 mm every 100 mm for the two horizontal axes, along the width and the length, of the road. On the other hand, these photovoltaic modules are not sufficiently resistant to static load if they are bonded directly onto the roadway. In other words, the roughness of the roadway may cause an indentation of the photovoltaic cells by the rear face of the photovoltaic module, then leading to risks of breakage of the photovoltaic cells.

Solutions have been envisaged for replacing the glass front face of photovoltaic modules by plastic materials, while conserving the conventional architecture and method of producing photovoltaic modules. As examples, patent application FR 2 955 051 A1 and the international applications WO 2012/140585 A1 and WO 2011/028513 A2 describe possibilities for alternatives to glass for designing the front face of photovoltaic modules, among which the use of polymer sheets, of a thickness less than or equal to 500 μm, such as polyvinylidene fluoride (PVDF), ethylene tetrafluoroethylene (ETFE), polymethylmethacrylate (PMMA) or polycarbonate (PC).

However, the simple substitution of glass by a polymer material, in order to obtain a light and flexible photovoltaic module, generally leads to increased vulnerability of the module to impacts and high mechanical loads, not acceptable for certain applications.

In addition, in these examples of embodiment of the prior art, the front face (without glass) of each photovoltaic module is continuous, that is to say that it forms a unit sheet or panel that covers the whole of the module. By so doing, the flexibility of each photovoltaic module may be limited and above all not sufficient. Furthermore, this also poses a problem of accentuation of differential expansion stresses between the different layers of the structure, being able to lead to undesirable deformations or disbondments at the interfaces of the structure, such as for example at the encapsulant/external layer interface.

Certain solutions have been proposed aiming to obtain a relative discontinuity of the front face of a photovoltaic module in order to obtain better flexibility of the module and to better manage differential expansion stresses. Thus, for example, patent application US 2014/0000683 A1 describes a method for encapsulating photovoltaic cells in an individual manner. The encapsulated cells may then be interconnected to obtain a supple photovoltaic module. Furthermore, patent application US 2014/0030841 A1 teaches the implementation of a photovoltaic module on a flexible substrate. The photovoltaic module is composed of “sub-modules” constituted of interconnected photovoltaic cells, each sub-module being electrically independent of neighbouring sub-modules.

Nevertheless, the solutions described above do not turn out to be totally satisfactory in terms of flexibility, resistance to impacts and mechanical loads, performance and cost of the photovoltaic modules, in particular for restrictive applications that place heavy demands on them with regard to their mechanical resistance.

### DESCRIPTION OF THE INVENTION

There thus exists a need to propose an alternative solution for designing an assembly provided with a photovoltaic module applied to a circulable zone to respond to at least some of the constraints inherent in applications targeted by the use of the photovoltaic module, in particular to improve the flexibility, the rigidity, the lightness and the resistance to impacts and mechanical loads of the photovoltaic module. There exists notably a need to further improve photovoltaic modules intended to be integrated in circulable zones, for pedestrians and/or vehicles, for example to increase their resistance to the load induced by the passage of a vehicle while having a certain flexibility.

The aim of the invention is to overcome at least partially the aforementioned needs and the drawbacks relating to the embodiments of the prior art.

The invention thus relates to, according to one of its aspects, a photovoltaic structure assembly, comprising:
a circulable zone,
a photovoltaic module applied to the circulable zone, the photovoltaic module comprising at least:
   a first transparent layer forming the front face of the photovoltaic module intended to receive a luminous flux,
   an assembly of a plurality of photovoltaic cells arranged side by side and electrically connected together,
   an assembly encapsulating the plurality of photovoltaic cells,
   a second layer forming the rear face of the photovoltaic module, intended in particular to be made integral with a circulable zone, the encapsulating assembly and the assembly of a plurality of photovoltaic cells being situated between the first and second layers, and
a fixation layer, constituted notably of a bituminous adhesive or one or more acrylic resins, situated between the circulable zone and the photovoltaic module, enabling the adherence of the photovoltaic module to the circulable zone,
   characterised in that the first layer is constituted of at least one transparent polymer material and comprises a plurality of panels independent of each other, each panel being situated facing at least one photovoltaic cell, so as to form a discontinuous front face of the photovoltaic module,
   and in that the rigidity of the encapsulating assembly is defined by a Young's modulus of the encapsulation material greater than or equal to 75 MPa at ambient temperature and a thickness of the layer comprised between 0.4 and 1 mm.

Initially, that is to say before any rolling operation, the encapsulating assembly is constituted of two layers of encapsulation material, referred to as core layers, between which the assembly of a plurality of photovoltaic cells is encapsulated. Nevertheless, after the operation of rolling of the layers, the layers of encapsulation material have melted to form only a single layer (or assembly) in which the photovoltaic cells are immersed. Before any rolling operation, each layer of encapsulation material may thus have a rigidity defined by a Young's modulus of the encapsulation material greater than or equal to 75 MPa at ambient temperature and a thickness of the layer comprised between 0.2 and 1 mm, or even between 0.2 and 0.5 mm.

The assembly encapsulating the plurality of photovoltaic cells is thus constituted of two layers of encapsulation material, namely the layers of encapsulation material which before rolling are in direct contact with the photovoltaic cells.

The term “transparent” signifies that the material of the first layer forming the front face of the photovoltaic module is at least partially transparent to visible light, allowing at least around 80% of said light to pass.

In addition, the expression “panels independent of each other” is taken to mean that the panels are situated at a distance from each other, each forming a unit element independent of the first layer and of each other, superimposed on at least one photovoltaic cell. The joining of the assembly of these panels then forms the first layer with a discontinuous aspect.

Moreover, the term “encapsulant” or “encapsulated” should be taken to mean that the assembly of a plurality of photovoltaic cells is arranged in a volume, for example hermetically sealed, at least in part formed by the layers of encapsulation material, joined together after rolling.

Furthermore, the expression “circulable zone” designates any zone provided for the circulation of pedestrians and/or vehicles, such as for example a roadway (or road), a motorway, a bicycle path, an industrial platform, a square, a pavement, this list being in no way limiting.

In addition, the expression “ambient temperature” is taken to mean a temperature comprised between around 15 and 30° C.

Thanks to the invention, it may thus be possible to provide an alternative solution for the design of a photovoltaic structure assembly comprising a supple and relatively flexible photovoltaic module, and also sufficiently robust to withstand the impacts and mechanical loads undergone, notably after application on the circulable zone. In particular, the use of a discontinuous front face may confer a flexible character to the photovoltaic module notably making it possible to facilitate its application on a non-flat support, for example curved. In addition, the use of an encapsulation material of high rigidity on either side of the photovoltaic cells may make it possible to protect suitably the photovoltaic cells against the risk of a strong mechanical load or an impact, while limiting their bending, and thus limiting the risk of breakage. Moreover, the absence of use of a glass material for the front face of the photovoltaic module may enable the photovoltaic module to have a weight less than that of a photovoltaic module according to the prior art, typically of the order of 12 kg/m², as a function of the thickness of the different layers used. Finally, the use of a discontinuous front face made of a polymer material may make it possible to protect against problems of thermal expansion in the course of using the photovoltaic module outside. In fact, since thermal expansion is proportional to the dimensions of the first layer forming the front face of the module, the fact of using panels having dimensions close to those of the photovoltaic cells may make it possible to limit significantly movements induced by thermal stresses, which can give rise to delaminations or non-controlled conformation of the photovoltaic module.

The photovoltaic structure assembly according to the invention may further comprise one or more of the following characteristics taken in isolation or according to any technically possible combinations thereof.

The second layer forming the rear face of the photovoltaic module may also be discontinuous. In other words, the second layer may also comprise a plurality of panels independent of each other, each panel being situated facing, that is to say superimposed, on at least one photovoltaic cell. The presence of a discontinuous rear face on the photovoltaic module may for example make it possible to improve further the flexibility of the module to facilitate the application thereof on a circulable zone provided with a surface roughness.

Furthermore, even though the first layer forming the front face of the photovoltaic module, and potentially the second layer forming the rear face of the module, have a discontinuous aspect, the assembly of a plurality of photovoltaic cells and the encapsulating assembly are advantageously continuous.

According to a particular embodiment of the invention, each panel of the first layer, and potentially of the second layer, may be situated facing several photovoltaic cells. This may notably be the case for photovoltaic cells of dimensions smaller than those of conventional photovoltaic cells, typically of 156×156 mm.

In addition, when a single photovoltaic cell is situated facing each panel of the first layer, and potentially of the second layer, each panel may have dimensions at least equal to those of the photovoltaic cell on which it is superimposed.

The photovoltaic module is advantageously without a first layer forming the front face of the module made of glass. Thus, as indicated previously, it may be possible to improve the lightness and the integration capacity of the photovoltaic module.

The encapsulation material forming the two core layers of encapsulation material of the encapsulating assembly may have a Young's modulus at ambient temperature greater than or equal to 100 MPa, notably greater than or equal to 150 MPa, or even 200 MPa. It is notably 220 MPa.

The encapsulating assembly may be formed from two layers of encapsulation material having identical or different thicknesses.

The second layer forming the rear face of the photovoltaic module may in a preferential manner be constituted of at least one composite material, notably of the polymer/glass fibre type.

The second layer furthermore has, preferably, a coefficient of thermal expansion less than or equal to 20 ppm, and preferably less than or equal to 10 ppm.

The second layer forming the rear face of the photovoltaic module may or may not be transparent.

The rigidity of the second layer forming the rear face of the photovoltaic module may be defined by a rigidity factor, corresponding to the Young's modulus at ambient temperature of the material of the second layer multiplied by the thickness of the second layer, comprised between 5 and 15 GPa·mm.

In addition, the rigidity of the second layer forming the rear face of the photovoltaic module may be defined by a Young's modulus at ambient temperature of the material of the second layer greater than or equal to 1 GPa, better greater than or equal to 3 GPa, even better greater than or equal to 10 GPa, and a thickness of the second layer comprised between 0.2 and 3 mm.

In this way, the second layer forming the rear face of the photovoltaic module may have a high rigidity, which can thus limit its flexibility. Nevertheless, the high rigidity may make it possible to reduce, or even prevent the indentation of the photovoltaic cells by the rear face of the module, that is to say the appearance of fissures and/or breakages of photovoltaic cells, when it is applied to a support having high surface roughness.

The spacing between two neighbouring, or instead consecutive or adjacent, photovoltaic cells may be greater than or equal to 1 mm, notably comprised between 1 and 30 mm, and preferably greater than or equal to 3 mm, notably comprised between 10 and 20 mm.

The two neighbouring photovoltaic cells considered may be two neighbouring cells of a same series (also known as a “string”) or two neighbouring cells belonging respectively to two series consecutive to the assembly of photovoltaic cells.

The presence of an important spacing between the photovoltaic cells may make it possible to obtain a spacing that is also important between the panels of the first layer forming the front face of the photovoltaic module. In this way, the discontinuous aspect of the front face of the module is accentuated, thus making it possible to confer flexibility to the module to facilitate its application on the circulable zone.

Advantageously, the spacing between two neighbouring panels of the first layer, and potentially of the second layer, is less than or equal to the spacing between two neighbouring photovoltaic cells.

The module may moreover preferentially comprise a so-called “cushioning” intermediate layer situated between the first layer forming the front face of the photovoltaic module and the assembly encapsulating the plurality of photovoltaic cells, enabling the assembly, notably by bonding, of the first layer on the encapsulating assembly.

The intermediate layer may be constituted of at least one polymer material, notably a thermoplastic or thermosetting polymer resin.

The intermediate layer may be for example in the form of sheet or in liquid form. It may be adhesive, for example of PSA type, or not. It may be implemented hot or instead at ambient temperature.

The rigidity of the intermediate layer may be defined by a Young's modulus of the material of the intermediate layer less than or equal to 50 MPa at ambient temperature and a thickness of the intermediate layer comprised between 0.01 and 1 mm.

The intermediate layer may in particular fulfil two main functions. On the one hand, it may enable the adhesion of the first layer forming the front face of the photovoltaic module on the encapsulating assembly for the case where the two layers are not chemically compatible. On the other hand, it may make it possible to create within the photovoltaic module a “cushioning” layer of a certain suppleness making it possible to improve the resistance to impacts and to mechanical loads of the module.

This intermediate layer may be optional, in particular absent when there is chemical compatibility between the first layer forming the front face of the photovoltaic module and the encapsulating assembly.

The photovoltaic module may further comprise an adhesive layer situated between the second layer forming the rear face of the photovoltaic module and the assembly encapsulating the plurality of photovoltaic cells, enabling the assembly, notably by bonding, of the second layer on the encapsulating assembly.

“Adhesive layer” is taken to mean a layer enabling, once the photovoltaic module has been produced, the second layer to adhere to the encapsulating assembly. It thus involves a layer enabling chemical compatibility and adhesion between the encapsulant and the rear face.

Furthermore, the thickness of the first layer forming the front face of the photovoltaic module may be greater than or equal to 0.1 mm, notably comprised between 0.5 and 6 mm.

The circulable zone may have surface roughness.

Furthermore, as indicated previously, the assembly comprises a fixation layer, notably by bonding, situated between the circulable zone and the photovoltaic module. The use of the fixation layer may make it possible to obtain a reinforced rear face of the photovoltaic module, making it possible to avoid the risk of indentation of the photovoltaic cells by the rear face when the circulable zone has high surface roughness and when the photovoltaic module is subjected to impact or high mechanical load. In fact, the interface between the rear face of the module and the circulable zone may thus be filled by a protective binder.

The fixation layer may comprise an adhesive, for example an epoxy or polyurethane adhesive, among others. It may in particular comprise a special industrial adhesive.

The fixation layer may also comprise a bituminous binder, potentially reinforced by the addition of a polymer such as Styrene-Butadiene-Styrene (SBS), hot or in emulsion.

According to an embodiment, the fixation layer is directly spread on the surface of the circulable zone, spread out in a thin layer, then the photovoltaic module is deposited thereon while the adhesive has not hardened or while the bituminous binder is still viscous and tacky.

In addition, the assembly may comprise a covering layer, enabling notably the passage of pedestrians and/or vehicles, applied on the first layer forming the front face of the photovoltaic module, the covering layer being non-opaque and having a textured and irregular outer surface, notably an irregularly macrotextured and microtextured outer surface, with a mean texture depth MTD measured according to the NF EN 13036-1 standard comprised between 0.2 mm and 3 mm and a PSV (Polished Stone Value) according to the NF EN 13043 standard of at least PSV₄₄, better PSV₅₀, even better PSV₅₃.

The covering layer may advantageously have an outer surface reproducing the texture of a circulable surface road dressing.

The term “irregularly” is taken to mean that the reliefs giving macrotexture and microtexture to the covering layer do not all have the same shape, or the same size. These reliefs may be obtained from texturing elements not having the same shape or the same size, being non-calibrated.

The covering layer advantageously has a transparency level greater than 50%, for example comprised between 50 and 95%, in a range of 100 nm around the efficiency peak of the photovoltaic cells, notably in the range 500-700 nm.

The mean texture depth MTD of the covering layer may be at least 0.30 mm, better at least 0.6 mm.

In addition, the covering layer may comprise a non-opaque matrix, preferably of Young's modulus at ambient temperature comprised between 0.1 and 10 GPa. The matrix may be selected from materials of synthetic or plant origin, bituminous binders, preferably of penetrability class according to the EN 1426 standard of 160/220, 100/150, 70/100, 50/70, 40/60, 35/50, 30/45 or 20/30 (in tenths of mm), clear road binders of synthetic or plant origin, preferably of penetrability class according to the EN 1426 standard of 160/220, 100/150, 70/100, 50/70, 40/60, 35/50, 30/45 or 20/30 (in tenths of mm) and polymeric binders.

The texture of the outer surface of the covering layer may be defined at least partially by non-opaque texturing elements, preferably of irregular, better random, shape. The texturing elements may be arranged according to a monolayer, preferably driven to around mid-thickness into the matrix of the covering layer. These texturing elements may be selected from granulates of transparent or translucent, organic or mineral materials, notably polycarbonate or glass. They may have a size ranging from 0.1 mm to 10 mm, better 0.4 to 4 mm, even better 0.9 to 1.4 mm.

The covering layer may for example be a binder of bituminous type such as defined in the NF EN 12591 standard, such as the binder Bituclair sold by the firm Colas.

The covering layer may instead be a clear road binder of synthetic or plant origin, such as the Végécol or Végéclair binders sold by the firm Colas.

The covering layer may also be a binder of purely synthetic nature or of plant origin, the binder being preferably of organic nature, preferentially of polymeric nature, such as an acrylic, epoxy or polyurethane resin, such as epoxy varnishes known as Vernis D sold by the firm Résipoly, or instead a polyurethane Sovermol sold by the firm BASF.

Preferentially, the photovoltaic cells are so-called “crystalline” cells, that is to say based on silicon crystals or silicon polycrystals.

Moreover, the invention also relates to, according to another of its aspects, the use, for the application thereof on a circulable zone, notably a roadway, of a photovoltaic module comprising at least:
a first transparent layer forming the front face of the photovoltaic module intended to receive a luminous flux,
an assembly of a plurality of photovoltaic cells arranged side by side and electrically connected together,
an assembly encapsulating the plurality of photovoltaic cells,
a second layer forming the rear face of the photovoltaic module, the encapsulating assembly and the assembly of a plurality of photovoltaic cells being situated between the first and second layers,
   the first layer being constituted of at least one transparent polymer material and comprising a plurality of panels independent of each other, each panel being situated facing at least one photovoltaic cell, so as to form a discontinuous front face of the photovoltaic module,
   and the rigidity of the encapsulating assembly being defined by a Young's modulus of the encapsulation material greater than or equal to 75 MPa at ambient temperature and a thickness of the encapsulating assembly comprised between 0.4 and 1 mm,
   the photovoltaic module being applied on the circulable zone through the intermediary of a fixation layer, constituted notably of a bituminous adhesive or one or more acrylic resins.

Furthermore, the invention further relates to, according to another of its aspects, a method for producing a photovoltaic structure assembly as defined previously, comprising at least the following four successive steps of:

a) hot rolling at a temperature greater than 150° C. of the assembly of layers constituting the photovoltaic module apart from the first layer forming the front face of the photovoltaic module and a potential so-called “cushioning” intermediate layer, situated between the first layer and the assembly encapsulating the plurality of photovoltaic cells,

b) rolling at a temperature less than or equal to 150° C., better 125° C., for example at ambient temperature, of the first layer forming the front face of the photovoltaic module, and the potential intermediate layer, on the layers constituting the photovoltaic module rolled together in the course of the first step a),

c) application of a covering layer on the first layer forming the front face of the photovoltaic module, notably to enable the passage of pedestrians and/or vehicles, the covering layer being non-opaque and having a textured and irregular outer surface, notably an irregularly macrotextured and microtextured outer surface, with an average mean texture depth MTD measured according to the NF EN 13036-1 standard comprised between 0.2 mm and 3 mm and a PSV (Polished Stone Value) according to the NF EN 13043 standard of at least PSV₄₄, better PSV₅₀, even better PSV₅₃,

d) fixation of the photovoltaic module on a circulable zone to form the photovoltaic structure assembly, by means of a layer for fixing the photovoltaic structure assembly, constituted notably of a bituminous adhesive or one or more acrylic resins.

During the first step a) of rolling, the layers constituting the photovoltaic module concerned are thus the assembly of a plurality of photovoltaic cells, the encapsulating assembly and the second layer forming the rear face of the photovoltaic module.

In addition, before the implementation of the second step b), the panels of the first layer may advantageously be treated using Corona treatment equipment so as to obtain a surface energy greater than or equal to 48 dyn/cm.

The potential so-called “cushioning” intermediate layer may make it possible to facilitate the bonding of the first layer forming the front face of the module on the other layers. This intermediate layer is optional. It may notably not be necessary when chemical compatibility exists between the first layer forming the front face of the module and the encapsulating assembly.

As indicated previously, the thickness of the encapsulating assembly may be comprised between 0.4 and 1 mm, this resulting from the association by rolling of at least two layers of encapsulation material each having a thickness comprised between 0.2 and 0.5 mm. These two layers of encapsulation material may furthermore have different thicknesses.

Advantageously, the implementation of at least two steps of rolling in the method according to the invention for producing the photovoltaic module may make it possible to become free of potential problems of thermal expansion which can arise on account of the use of a front face of the module made of polymer material.

In fact, certain layers of the photovoltaic module need to be rolled at a temperature greater than or equal to 140° C., or even 150° C., but the rolling at this temperature level in a single step, in accordance with the practice according to the prior art, of the assembly of layers of the module, including that forming the front face of the module, may give rise to uncontrolled conformation and to important delaminations of the front face of the photovoltaic module due to generated mechanical stresses that are too high.

Also, the presence of at least one second step of rolling at a temperature lower than for the first step, for the rolling of the front face of the photovoltaic module, potentially combined with the presence of a so-called “cushioning” intermediate layer enabling the bonding of the front face of the module on the encapsulation material and the cushioning of thermal stresses, may make it possible to limit, or event to prevent, thermal expansion.

Alternatively, the invention also relates to, according to another of its aspects, a method for producing a photovoltaic structure assembly as defined previously, comprising at least the following three successive steps of:

a) hot rolling at a temperature greater than or equal to 150° C. of the assembly of layers constituting the photovoltaic module,

b) application of a covering layer on the first layer forming the front face of the photovoltaic module, notably to enable the passage of pedestrians and/or vehicles, the covering layer being non-opaque and having a textured and irregular outer surface, notably an irregularly macrotextured and microtextured outer surface, with a mean texture depth MTD measured according to the NF EN 13036-1 standard comprised between 0.2 mm and 3 mm and a PSV (Polished Stone Value) according to the NF EN 13043 standard of at least PSV₄₄, better PSV₅₀, even better PSV₅₃,

c) fixation of the photovoltaic module on a circulable zone to form the photovoltaic structure assembly, by means of a layer for fixing the photovoltaic structure assembly, constituted notably of a bituminous adhesive or one or more acrylic resins.

The photovoltaic structure assembly and the method according to the invention may comprise any of the aforementioned characteristics, taken in isolation or according to any technically possible combinations thereof with other characteristics.

### BRIEF DESCRIPTION OF THE DRAWING

The invention will be better understood on reading the detailed description that follows of an example of non-limiting implementation thereof and be examining the single FIGURE, schematic and partial, of the appended drawing, illustrating, in section and in exploded view, an example of embodiment of a photovoltaic structure assembly in accordance with the invention.

In this single FIGURE, the different parts are not necessarily represented according to a uniform scale, in order to make the FIGURE more legible.

### DETAILED DESCRIPTION OF A PARTICULAR EMBODIMENT

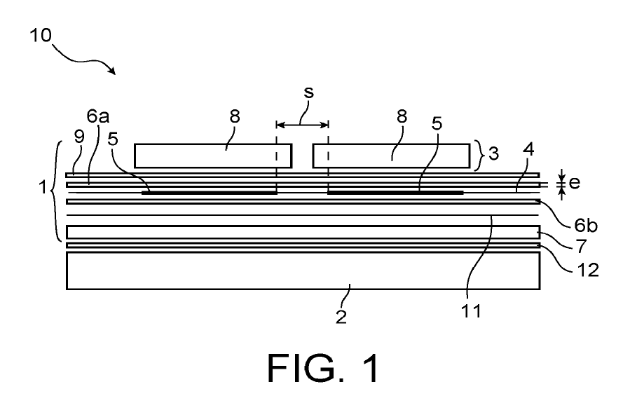

Reference is made hereafter to FIG. 1, illustrating in section and in exploded view an example of embodiment of a photovoltaic structure assembly 10 in accordance with the invention.

It should be noted that FIG. 1 corresponds to an exploded view of the photovoltaic structure assembly 10 before the rolling steps of the method according to the invention. Once the rolling steps have been carried out, the different layers are in reality superimposed on each other, but also a little deformed such that at least the panels 8 of the first layer 3 are pushed into the assembly formed by the intermediate layer 9 and the encapsulating assembly 6a, 6b which deform. The rolling steps ensure a hot, vacuum pressing. Depending on the thicknesses of the different layers, the panels 8 may be flush or not on the photovoltaic module 1, the material of the intermediate layer 9 and perhaps that of the encapsulating assembly 6a, 6b also being able to fill at least a part of the spaces between the panels 8.

As explained previously, the photovoltaic module 1 in accordance with the invention is designed to be sufficiently flexible in order to be able to apply it, notably by bonding, on a circulable zone 2, in particular a roadway, which can have a surface roughness, in other words not necessarily flat and smooth. In addition, the photovoltaic module 1 in accordance with the invention is also provided to withstand static or dynamic pressures that can go up to 1500 kN/m², or even 5000 kN/m². The circulable zone 2 is advantageously sufficiently rigid so as not to deform when the same stress is applied as that applied to the photovoltaic module 1.

As may thus be seen in FIG. 1, the photovoltaic module 1 comprises a first transparent layer 3 forming the front face of the module 1 intended to receive a luminous flux, an encapsulating assembly 6a, 6b, obtained by the melting of two layers of upper 6a and lower 6b encapsulation material, an assembly 4 of photovoltaic cells 5 taken between two layers of upper 6a and lower 6b encapsulation material, and a second layer 7 forming the rear face of the photovoltaic module 1 intended to be bonded to the circulable zone 2.

The two layers of encapsulation material 6a and 6b forming the encapsulating assembly, as well as the potential intermediate layer 9 described hereafter, form a relatively supple structure which can be produced from a single material or from several materials in the event of chemical incompatibility.

An accordance with the invention, the first layer 3 is constituted of a transparent polymer material and comprises a plurality of panels 8 independent of each other, each panel 8 being situated facing a photovoltaic cell 5, so as to form a discontinuous front face of the photovoltaic module 1.

The transparent polymer material of the first layer 3 may for example be selected from polycarbonate (PC), polymethyl methacrylate (PMMA), ethylene tetrafluoroethylene (ETFE), or polyvinylidene fluoride (PVDF), among others. In addition, the thickness of the first layer 3 may be greater than 0.1 mm, and ideally comprised between 0.5 and 6 mm. In this example, the first layer 3 is thus constituted of several panels 8, of dimensions equal to 162×162 mm, of PMMA of thickness equal to 3 mm.

Furthermore, the photovoltaic cells 5 are interconnected electrically to each other with a spacing s between two neighbouring cells 5 equal to around 15 mm. The photovoltaic cells 5 may be so-called “crystalline” cells, that is to say based on silicon crystals or silicon polycrystals, with a homojunction or heterojunction, and of thickness less than or equal to 250 μm. In addition, in this example, each panel 8 extends in superposition on either side of the underlying photovoltaic cell 5 over a distance of around 3 mm, such that the spacing between two adjacent panels 8 is here equal to the spacings between two neighbouring cells 5 reduced by around 2 times 3 mm, i.e. around 6 mm.

Moreover, the rigidity of each layer of encapsulation material 6a and 6b is defined by a Young's modulus E of the encapsulation material at ambient temperature greater than or equal to 50 MPa, or even 75 MPa, or instead even 100 MPa, preferably greater than or equal to 200 MPa, and a thickness e of the layer 6a, 6b comprised between 0.2 and 1 mm.

The layers of encapsulation material 6a and 6b form an encapsulating assembly preferentially selected to be an ionomer such as the ionomer sold under the name of Jurasol® of DG3 type by the firm Jura-plant or the ionomer sold under the name PV5414 by the firm Du Pont, having a Young's modulus at ambient temperature greater than or equal to 200 MPa and a thickness of around 500 μm.

The second layer 7 forming the rear face of the photovoltaic module 1 is for its part constituted of a polymer material such as thermosetting resins such as epoxy based resins, transparent or not, or a composite material, for example of the polymer/glass fibre type. In this example, the second layer 7 is constituted of a composite material of the polymer/glass fibre type, notably a fabric based on polypropylene and glass fibres with a glass fibre content of 60% by weight, such as Thermopreg® fabric P-WRt-1490-PP60W sold by the firm Owens Corning Vetrotex, having a thickness of around 1 mm and a Young's modulus at ambient temperature of around 12 GPa.

Furthermore, an adhesive layer 11, or instead compatibilising layer (its presence being justified in the event of chemical incompatibility), is situated between the second layer 7 forming the rear face of the photovoltaic module 1 and the encapsulating assembly formed by the two layers of encapsulation material 6a and 6b on either side of the assembly 4 of photovoltaic cells 5. This adhesive or compatibilising layer 11 enables the bonding of the second layer 7 on the lower layer of encapsulation material 6b. In the case of the use of Thermopreg® fabric P-WRt-1490-PP60W for the second layer 7, the compatibilising layer 11 is preferentially selected to be a film of Mondi TK41001 type having a thickness of around 50 μm.

In addition, as may be seen in FIG. 1, the photovoltaic module 1 also comprises a so-called “cushioning” intermediate layer 9 situated between the first layer 3 and the encapsulating assembly formed by the two layers of encapsulation material 6a and 6b on either side of the assembly 4 of photovoltaic cells 5.

The intermediate layer 9 enables the bonding of the first layer 3 on the upper layer of encapsulation material 6a.

The intermediate layer 9 is for example constituted of a standard encapsulant used in the photovoltaics field, such as the copolymer of ethylene vinyl acetate (EVA), a polyolefin, silicone, thermoplastic polyurethane, polyvinyl butyral, among others. It may further be constituted of a liquid resin of acrylic, silicone or polyurethane type, single component or two component, cross-linkable through heat or photochemically. It may also be constituted of a pressure sensitive adhesive (PSA).

In this example, the intermediate layer 9 is constituted of a thermoplastic film, namely the thermoplastic polyurethane also known by the acronym TPU, such the TPU of Dureflex® A4700 type sold by the firm Bayer or PX1001 sold by the firm American Polyfilm, of thickness equal to around 380 μm.

The intermediate layer 9 makes it possible to fulfil two main functions. On the one hand, it enables the adhesion of the first layer 3 on the upper layer of encapsulation material 6a for the case where the two layers are not chemically compatible. On the other hand, it makes it possible to create within the photovoltaic module 1 a “cushioning” layer of a certain suppleness making it possible to improve the resistance of the module 1 to impacts and mechanical loads.

Furthermore, the photovoltaic structure assembly 10 in accordance with the invention represented in FIG. 1 also comprises a circulable zone 2. The circulable zone 2 may be of variable rigidity. In this example, it corresponds quite particularly to a road type asphalt surface.

In order to enable the bonding of the photovoltaic module 1 on the circulable zone 2, the assembly 10 also comprises a fixation layer 12. Said fixation layer 12 is constituted by a bituminous adhesive enabling the module 1 to be made to adhere to the roadway or route. In this example, it is a bitumen of ColFlex N type sold by the firm Colas, with an incorporation rate of 1 kg/m². The use of a bituminous adhesive 12 associated with a rear face 7 of the module 1 made of a composite material may make it possible to reinforce the rear face 7 so as to avoid the risk of indentation of the photovoltaic cells 5 subjected to the passage of pedestrians and/or vehicles on a rough roadway 2. The bituminous adhesive 12 thus plays the role of a protective binder filling the interface between the roadway 2 and the rear face 7 of the module 1.

Moreover, although not represented in FIG. 1, the photovoltaic structure assembly 10 also comprises a covering layer applied to the first layer 3, intended to facilitate the circulation of pedestrians and/or vehicles.

The covering layer is non-opaque and has a textured and irregular outer surface, notably an irregularly macrotextured and microtextured outer surface, with a mean texture depth MTD measured according to the NF EN 13036-1 standard comprised between 0.2 mm and 3 mm and a PSV value according to the NF EN 13043 standard of at least PSV₄₄, or even PSV₅₀, or instead even PSV₅₃.

A method for producing a photovoltaic structure assembly 10 in accordance with the invention will now be described.

The method comprises a first step a) of hot rolling at a temperature of around 170° C. and under vacuum (pressure less than or equal to 10 mbars) of the constituent layers 6a, 4, 6b, 11 and 7 of the photovoltaic module 1 apart from the first layer 3 and the intermediate layer 9. This first step a) of rolling is carried out for around 15 minutes so as to obtain a “laminate” of encapsulated photovoltaic cells 5. The rolling parameters, such as the temperature, the time and the pressure, may nevertheless depend on the encapsulating material used.

Then, the method comprises a second step b) of hot rolling at a temperature of around 125° C. and under vacuum of the “laminate” obtained in the course of the first step a) with the first layer 3 forming the front face of the photovoltaic module 1 by means of the intermediate layer 9. This second step b) is carried out for a duration of around 30 minutes so as to obtain the photovoltaic module 1. Before the implementation of this second step b), the panels 8 of the first layer 3 may advantageously be treated by means of a Corona treatment equipment so as to obtain a surface energy greater than or equal to 48 dyn/cm.

These first a) and second b) rolling steps are then followed by a step c) of application of a covering layer on the first layer 3 to enable the passage of pedestrians and/or vehicles, the covering layer being as described previously. Finally, a step of fixation d) of the photovoltaic module 1 on the circulable zone 2 makes it possible to form the photovoltaic structure assembly 10. This fixation step is advantageously implemented by means of a bituminous adhesive applied between the circulable zone 2 and the module 1.

Tests have been able to be carried out with different photovoltaic modules 1, comprising from 3 to 40 photovoltaic cells 5, according to the method described above. The mechanical load resistance of these modules 1, bonded onto a road asphalt 2, with static and dynamic pressures ranging up to 500 kN/m², has been able to be demonstrated. For example, a photovoltaic module 1, constituted of three photovoltaic cells 5, did not undergo any degradation after around 64000 applications of a pressure of 500 kN/m².

Consequently, the photovoltaic module 1 may have an increased mechanical resistance suited to restrictive applications in terms of mechanical loads, such as of the solar roadway type, but also have a piecewise flexibility on account of the presence of a discontinuous front face 3, enabling it to take different shapes to adapt to different types of surfaces, for example uneven or of imperfect flatness. In addition, the presence of a reinforced rear face 7 may make it possible to improve the indentation resistance of this rear face 7 of the module 1, said indentation being able to result in the roughness of the support 2 on which the module 1 is applied and being able to lead to fissures of the photovoltaic cells 5 of the photovoltaic module 1.

Obviously, the invention is not limited to the example of embodiment that has just been described. Various modifications may be made thereto by those skilled in the art.

The expression “comprising a” should be understood as being synonymous with “comprising at least one”, unless specified otherwise.

1-16. (canceled)

17: A photovoltaic structure assembly, comprising:
a circulable zone;
a photovoltaic module applied to the circulable zone;
the photovoltaic module comprising:
a first transparent layer forming a front face of the photovoltaic module configured to receive a luminous flux,
an assembly of a plurality of photovoltaic cells arranged side by side and electrically connected together,
an assembly encapsulating the plurality of photovoltaic cells, and
a second layer forming a rear face of the photovoltaic module, the encapsulating assembly and the assembly of a plurality of photovoltaic cells being situated between the first and second layers; and
a fixation layer, including a bituminous adhesive or one or more acrylic resins, situated between the circulable zone and the photovoltaic module, enabling adherence of the photovoltaic module to the circulable zone,
wherein the first layer includes at least one transparent polymer material and a plurality of panels independent of each other, each panel being situated facing at least one photovoltaic cell, to form a discontinuous front face of the photovoltaic module, and
wherein rigidity of the encapsulating assembly is defined by a Young's modulus of the encapsulation material greater than or equal to 75 MPa at ambient temperature and a thickness of the encapsulating assembly is between 0.4 and 1 mm.

18: An assembly according to claim 17, further comprising a covering layer, applied to the first layer forming the front face of the photovoltaic module, the covering layer being non-opaque and having a textured and irregular outer surface, with a mean texture depth MTD measured according to the NF EN 13036-1 standard between 0.2 mm and 3 mm and a PSV value according to the NF EN 13043 standard of at least PSV₄₄.

19: An assembly according to claim 17, wherein the circulable zone is provided for circulation of pedestrians and/or vehicles.

20: An assembly according to claim 17, wherein the encapsulation material of the layers forming the encapsulating assembly has a Young's modulus at ambient temperature greater than or equal to 100 MPa.

21: An assembly according to claim 17, wherein the second layer forming the rear face of the photovoltaic module includes at least one composite material.

22: An assembly according to claim 17, wherein the rigidity of the second layer forming the rear face of the photovoltaic module is defined by a rigidity factor, corresponding to the Young's modulus at ambient temperature of the material of the second layer multiplied by the thickness of the second layer, between 5 and 15 GPa·mm.

23: An assembly according to claim 17, wherein spacing between two neighbouring photovoltaic cells is greater than or equal to 1 mm.

24: An assembly according claim 17, wherein the photovoltaic module comprises an intermediate layer situated between the first layer forming the front face of the photovoltaic module and the assembly encapsulating the plurality of photovoltaic cells, enabling assembly of the first layer on the encapsulating assembly.

25: An assembly according to claim 24, wherein the intermediate layer includes at least one polymer material.

26: An assembly according to claim 24, wherein the rigidity of the intermediate layer is defined by a Young's modulus at ambient temperature of the material of the intermediate layer less than or equal to 50 MPa and a thickness of the intermediate layer between 0.01 and 1 mm.

27: An assembly according to claim 17, wherein the photovoltaic module further comprises an adhesive layer situated between the second layer forming the rear face of the photovoltaic module and the encapsulating assembly formed by two layers of encapsulation material on either side of the plurality of photovoltaic cells, enabling assembly of the second layer on the encapsulating assembly.

28: An assembly according to claim 17, wherein the thickness of the first layer forming the front face of the photovoltaic module is greater than or equal to 0.1 mm.

29: An assembly according to claim 17, wherein the photovoltaic cells are based on silicon crystals or silicon polycrystals.

30: Use, for application thereof on a circulable zone of a photovoltaic module comprising:
a first transparent layer forming a front face of the photovoltaic module configured to receive a luminous flux;
an assembly of a plurality of photovoltaic cells arranged side by side and electrically connected together;
an assembly encapsulating the plurality of photovoltaic cells;
a second layer forming a rear face of the photovoltaic module, the encapsulating assembly and the assembly of a plurality of photovoltaic cells being situated between the first and second layers,
the first layer including at least one transparent polymer material and including a plurality of panels independent of each other, each panel being situated facing at least one photovoltaic cell, to form a discontinuous front face of the photovoltaic module, and
rigidity of the encapsulating assembly being defined by a Young's modulus of the encapsulation material greater than or equal to 75 MPa at ambient temperature and a thickness of the encapsulating assembly is between 0.4 and 1 mm,
the photovoltaic module being applied to the circulable zone through an intermediary of a fixation layer, including a bituminous adhesive or one or more acrylic resins.

31: A method for producing a photovoltaic structure assembly according to claim 17, comprising:
a) hot rolling at a temperature greater than 150° C. of an assembly of the layers constituting the photovoltaic module apart from the first layer forming the front face of the photovoltaic module and a potential intermediate layer, situated between the first layer and the assembly encapsulating the plurality of photovoltaic cells;
b) rolling at a temperature less than or equal to 150° C., of the first layer forming the front face of the photovoltaic module, and the intermediate layer, on the layers constituting the photovoltaic module rolled together during a);
c) application of a covering layer on the first layer forming the front face of the photovoltaic module, the covering layer being non-opaque and having a textured and irregular outer surface with a mean texture depth MTD measured according to the NF EN 13036-1 standard between 0.2 mm and 3 mm and a PSV value according to the NF EN 13043 standard of at least PSV₄₄;
d) fixing the photovoltaic module on the circulable zone to form the photovoltaic structure assembly, by a layer for fixing the photovoltaic structure assembly.

32: A method for producing a photovoltaic structure assembly according to claim 17, comprising:
a) hot rolling at a temperature greater than or equal to 150° C. of an assembly of the layers constituting the photovoltaic module;
b) application of a covering layer on the first layer forming the front face of the photovoltaic module, the covering layer being non-opaque and having a textured and irregular outer surface with a mean texture depth MTD measured according to the NF EN 13036-1 standard between 0.2 mm and 3 mm and a PSV value according to the NF EN 13043 standard of at least PSV₄₄;
c) fixing the photovoltaic module on the circulable zone to form the photovoltaic structure assembly, by a layer for fixing the photovoltaic structure assembly.
